(19) United States
(12) Patent Application Publication
(10) Pub. No.: US 2005/0026326 A1
(43) Pub. Date: Feb. 3, 2005

(54) Manufacturing method of semiconductor device

(76) Inventors: Mika Kiritani, Kanagawa (JP); Shinya Takyu, Saitama (JP); Kazuhiro Iizuka, Kanagawa (JP)

Correspondence Address: Finnegan, Henderson, Farabow,;Garrett & Dunner, L.L.P., 1300 I Street, N.W., Washington, DC, 20005-3315, US

(21) Appl. No.: 10/843,478

(22) Filed: May 12, 2004

(30) Foreign Application Priority Data
May 12, 2003 (JP) 2003-132674

(51) Int. Cl. H01L 21/44

(52) U.S. Cl. 438/108

(57) ABSTRACT

A manufacturing method of a semiconductor device to electrically connect a semiconductor chip and a wiring board via a first bump electrode, at least one of the semiconductor chip and the wiring board having a second bump electrode or a connection electrode, the method includes: collectively performing flip chip bonding of the semiconductor chip to the wiring board and resin sealing processing between the semiconductor chip and the wiring board; wherein the collective processing includes controlling viscosity of a sealing resin with ultrasonic vibration so that the first bump electrode penetrates the sealing resin; and using the ultrasonic vibration to electrically connect the first bump electrode to the second bump electrode when at least one of the semiconductor chip and the wiring board has the second bump electrode, or using the ultrasonic vibration to electrically connect the first bump electrode to the connection electrode when at least one of the semiconductor chip and the wiring board has the connection electrode.

### CROSS REFERENCE TO RELATED APPLICATION

This application claims benefit of priority under 35 USC § 119 to Japanese Patent Application No. 2003-132674, filed on May 12, 2003, the content of which are incorporated by reference herein.

### BACKGROUND OF THE INVENTION

1. Field of the Invention

The present invention relates to a manufacturing method of a semiconductor device, and for example, relates to a manufacturing method of a type of semiconductor device in which a semiconductor chip (hereinafter referred to as a chip) is flip-chip-connected to a wiring board, and the method comprises collectively performing flip chip bonding and resin sealing.

2. Related Background Art

The following manufacturing processes have heretofore been known in a manufacturing method of a semiconductor device.

First, a semiconductor element is formed on a wafer of silicon or the like in a known process. Next, a bump electrode (hereinafter referred to as a bump) electrically connected to the semiconductor element is formed on a main surface of the wafer on which the semiconductor element has been formed. Then, a surface protection tape is affixed onto the wafer main surface before grinding of a rear surface to reduce thickness of the wafer. Subsequently, a dicing tape is affixed onto the element formation surface (main surface) of the wafer whose thickness has been reduced, and the wafer is diced (full cut dicing) from a rear surface side by a diamond blade, a laser blade or the like to be separated into chips. Further, each chip is picked up by sucking the rear surface thereof with a suction tool (collet). At the same time, a sealing resin is applied to a wiring board (the sealing resin may be applied to the chip in advance.), and then the chip is affixed to the wiring board to which the resin is applied so as that mounting through flip chip bonding and resin sealing is achieved.

Heretofore, the manufacturing processes as described above have often been utilized in the type of semiconductor device in which the semiconductor chip is flip-chip-bonded to the wiring board and the resin sealing is conducted between the chip and the wiring board.

In one of the processes for flip-chip-bonding the chip to the wiring board and conducting the resin sealing between the chip and the wiring board, generally, a connection electrode (hereinafter referred to as a pad or a pad electrode) of the wiring board and a pad of the chip are heated with the bump placed therebetween so as to connect them together, and then the resin is filled between the chip and the wiring board to form a resin sealed material. In this case, the bump may be attached to the chip in advance. Alternatively, the bump may be attached to the wiring board. Moreover, the bumps may be attached to both the wiring board and the chip. In this case, the bumps which are attached to them and face each other are combined into one bump.

Furthermore, there is a method of disposing the sealing resin between the chip and the wiring board before the flip chip bonding in order to simplify the process. The bump attached to the chip (or the wiring board) is placed opposite to the pad of the wiring board (or the chip) so as to sandwich the resin in paste or film state. The bumps respectively attached to the chip and the wiring board are oppositely placed. Thus, the bump and the pad, or the bumps are connected and then heated and press-bonded, thereby collectively accomplishing the flip chip bonding and the resin sealing.

Furthermore, a bonding technique using ultrasonic vibration has been introduced to ensure efficient flip chip bonding. In conventional flip chip bonding techniques using the ultrasonic vibration, the wiring board is sucked to a fixing jig called a stage which can be heated, and the chip is sucked by a device called a tool with a mechanism capable of pressurizing and applying ultrasonic wave or heating in addition to pressurizing and applying ultrasonic wave, thereby achieving mounting. At this moment, the element formation surface of the chip is placed opposite to an interconnection and pad formation surface of the wiring board in order to bond the bump formed on the pad of the chip to a plated bump or stud bump formed to be connected to an interconnection of the wiring board, thus putting weight while applying the ultrasonic vibration from the tool to the chip (e.g., Japanese Patent Publication Laid-open No. 8-45994).

However, in the conventional process of collectively performing the flip chip bonding and the resin sealing, if the flip chip bonding and the resin sealing are performed at a high temperature, the bump can not penetrate the resin, and the resin intervenes between the bump and the pad on the wiring board to cause a conduction failure in some cases. FIG. 9 is a photographic view illustrating a conventional connection state between the bump and the pad, wherein the resin intervenes between the pad and the bump. Further, voids might be produced between the chip and the wiring board, and the resin sealed material, and between the wiring board and the resin sealed material, impairing reliability of the semiconductor device.

### BRIEF SUMMARY OF THE INVENTION

According to a first aspect of the present invention, there is provided a manufacturing method of a semiconductor device to electrically connect a semiconductor chip and a wiring board via a first bump electrode, at least one of the semiconductor chip and the wiring board having a second bump electrode or a connection electrode, the method comprising:
collectively performing flip chip bonding of the semiconductor chip to the wiring board and resin sealing processing between the semiconductor chip and the wiring board;
wherein the collective processing includes controlling viscosity of a sealing resin with ultrasonic vibration so that the first bump electrode penetrates the sealing resin; and using the ultrasonic vibration to electrically connect the first bump electrode to the second bump electrode when at least one of the semiconductor chip and the wiring board has the second bump electrode, or using the ultrasonic vibration to electrically connect the first bump electrode to the connection electrode when at least one of the semiconductor chip and the wiring board has the connection electrode.

According to a second aspect of the present invention, there is provided a manufacturing method of a semiconductor device to electrically connect a semiconductor chip and a wiring board via a first bump electrode, at least one of the semiconductor chip and the wiring board having a second bump electrode or a connection electrode, the method comprising:
collectively performing flip chip bonding of the semiconductor chip to the wiring board and resin sealing processing between the semiconductor chip and the wiring board;
wherein the collective processing includes controlling viscosity of a sealing resin with a heating treatment so that the first bump electrode penetrates the sealing resin; and using ultrasonic vibration to electrically connect the first bump electrode to the second bump electrode when at least one of the semiconductor chip and the wiring board has the second bump electrode, or using the ultrasonic vibration to electrically connect the first bump electrode to the connection electrode when at least one of the semiconductor chip and the wiring board has the connection electrode.

### BRIEF DESCRIPTION OF THE DRAWINGS

In the accompanying drawings:

FIG. 1A is a sectional view of a chip to which a first embodiment of the present invention is applied;

FIG. 1B is a sectional view of a wiring board to which the first embodiment of the present invention is applied;

FIGS. 2 to 4 are sectional views explaining a process of performing flip chip bonding after a resin is applied to the wiring board, in the first embodiment of the present invention;

FIG. 5 is a diagram showing temperature dependency of resin viscosity before hardening of a sealing resin made of epoxy resin or the like which is a thermosetting resin, in the first embodiment of the present invention;

FIG. 6 is a diagram showing frequency dependency on ultrasonic vibration of the resin viscosity before the hardening of the sealing resin made of epoxy resin or the like which is the thermosetting resin, in the first embodiment of the present invention;

FIG. 7 is a view explaining a connection state of a bump and a pad in the first embodiment of the present invention;

FIGS. 8A and 8B are sectional views explaining a process of performing flip chip bonding after the resin is applied to the chip in a second embodiment of the present invention; and

FIG. 9 is a view explaining the connection state of the bump and the pad according to a conventional technique.

### DETAILED DESCRIPTION OF THE INVENTION

Embodiments of the invention will hereinafter be described in reference to the drawings.

In the following embodiment, a process of collective connection and resin sealing is performed by use of ultrasonic vibration under a condition at 100° C. A sealing resin is softened so that a bump completely penetrates the sealing resin, and then the bump is brought into contact with and bonded to a pad formed on a wiring board. In order to maintain the bonding temperature and resin sealing temperature, the sealing resin is adequately fused, and a temperature at which viscosity thereof is the lowest is selected. This makes it possible for the bump to penetrate the sealing resin.

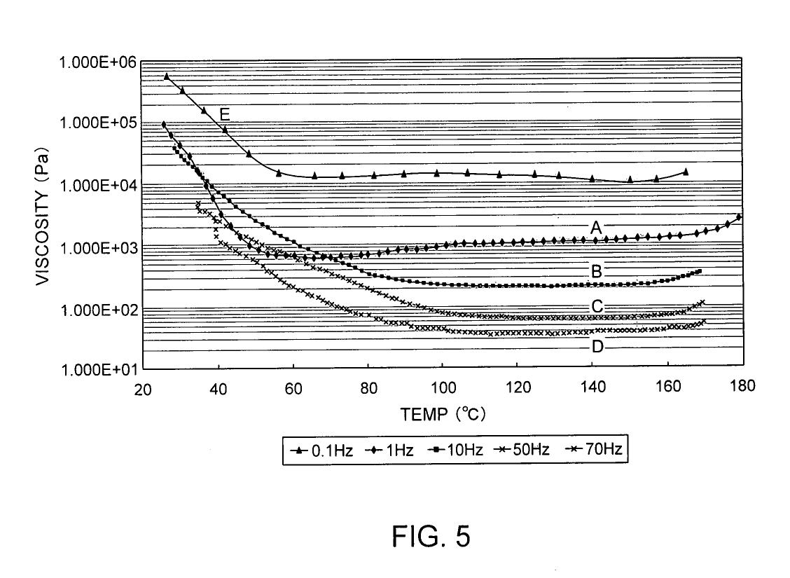

FIG. 5 is a diagram showing temperature dependency of the resin viscosity before hardening of the sealing resin made of epoxy resin or the like which is a thermosetting resin. The vertical axis of the diagram indicates the resin viscosity (Pa·S), and the horizontal axis of the diagram indicates resin temperature (TEMP (° C.)). Temperature curves A to E of the resin viscosity are dependent upon frequency of the ultrasonic vibration. The temperature curve A is at a frequency of 1 Hz, the temperature curve B at a frequency of 10 Hz, the temperature curve C at a frequency of 50 Hz, the temperature curve D at a frequency of 79 Hz, and the temperature curve E at a frequency of 0.1 Hz. As shown, the resin viscosity before the hardening of the resin changes depending on the temperature, and the resin rapidly hardens (the viscosity increases) in a temperature area higher than a temperature area indicated within a range of 160 to 180° C. in which hardening starts (hardening starting area). The viscosity is lower at the temperature immediately before the hardening starting area than in the area at a lower temperature. This area is called a low viscosity area. The manufacture of a semiconductor device according to the above embodiment should preferably be performed in this low viscosity area, but is not limited to this area. This is because the viscosity is also changed by the ultrasonic vibration. As indicated by the temperature curves A to E, the resin viscosity is lower at higher frequencies. Therefore, the frequency of the ultrasonic vibration can be controlled to adjust the resin viscosity.

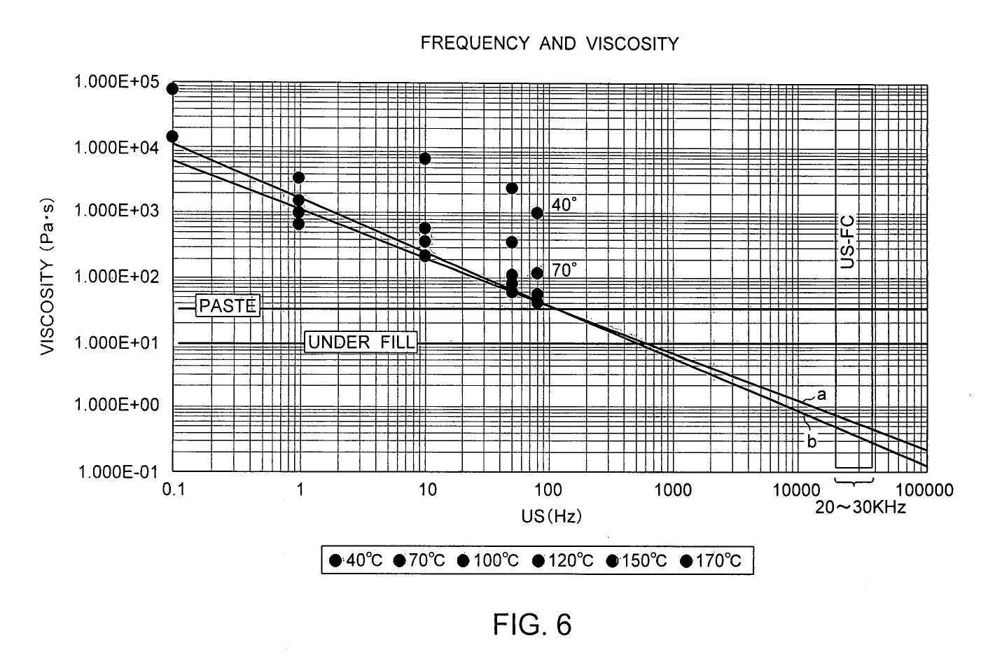

FIG. 6 is a diagram showing frequency dependency on the ultrasonic vibration of the resin viscosity before the hardening of the sealing resin made of epoxy resin or the like which is the thermosetting resin. The vertical axis of the diagram indicates the resin viscosity (Pa·S), and the horizontal axis of the diagram indicates the frequency (US (Hz)) of the ultrasonic vibration. A characteristic line a is a resin viscosity-frequency characteristic line at a processing temperature of 120° C., and a characteristic line b is a resin viscosity-frequency characteristic line at a processing temperature of 100° C. (corresponding to the temperature at which the following embodiment is implemented). Further, the viscosity indicated by “paste” is that of the paste to form a resin sealed material between a chip and a wiring board when the chip is flip-chip-bonded to the wiring board. The viscosity indicated by “under fill” is the resin viscosity when the resin is run between the chip and the wiring board that are flip-chip-bonded. As shown in FIG. 6, the viscosity linearly changes in accordance with the frequency of the ultrasonic vibration. Since the manufacturing method of the semiconductor device in the embodiment described later can be implemented at the resin viscosity lower than the resin viscosity during formation of the resin sealed material with the paste or than the resin viscosity during formation of the under fill, a range of 100 Hz to 100 kHz is appropriate for a frequency range of the ultrasonic vibration in the following embodiment. In this range, the resin viscosity of the sealing resin can be adjusted to a suitable value for implementing the manufacturing method in the following embodiment. Predetermined resin viscosity can rarely been obtained if the manufacturing method in the following embodiment is implemented at a value lower than 100 Hz. The resin viscosity becomes higher at a relatively low implementation temperature of 40° C., 70° C. or the like. The following embodiments are implemented within a range of approximately 20 to approximately 30 kHz (US-FC zone).

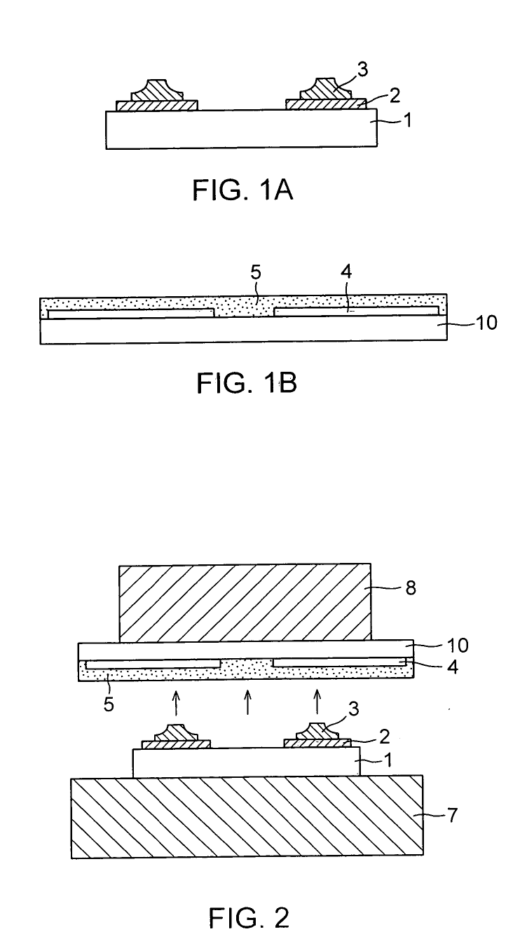

Next, a first embodiment will be described referring to FIGS. 1 to 4 and 7.

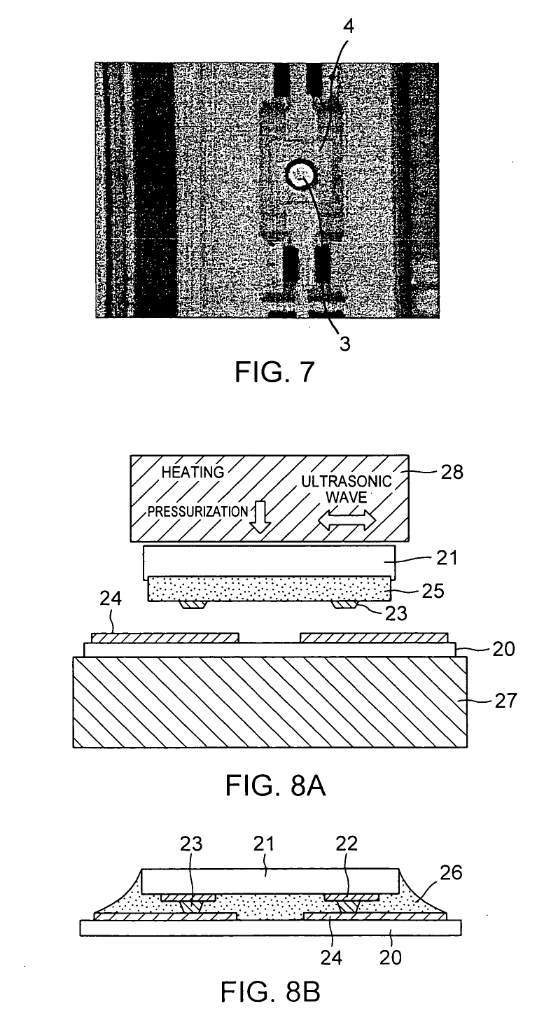

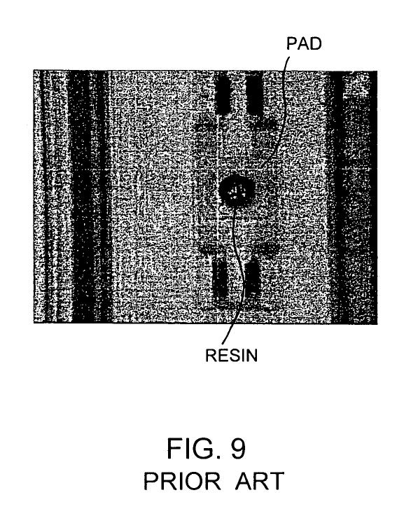

FIGS. 1A and 1B are sectional views of the chip and the wiring board, respectively, FIGS. 2 to 4 are sectional views explaining a process of performing flip chip bonding after applying resin onto the wiring board, and FIG. 7 is a photographic view explaining a connection state of the bump and the pad according to this embodiment.

A flip chip type semiconductor device is constituted of the wiring board such as a printed wiring board comprising an external connection terminal, a semiconductor chip flip-chip-connected to the wiring board, and the resin sealed material filled between the semiconductor chip and the wiring board. A chip 1 into which a semiconductor element or an integrated circuit is incorporated is obtained by dicing a semiconductor wafer made of silicon or the like. An insulating film such as a silicon oxide film, a silicon nitride film or a low dielectric constant insulating film called a Low-k film is used for such purposes as interlayer insulation between the semiconductor element and the integrated circuit. A passivation film is formed on the insulation film. A bump 3 such as solder to be a terminal is exposed from the passivation film. The bump 3 is electrically connected to the inside semiconductor element or integrated circuit which is not shown, and the bump 3 is formed on a pad 2 made of aluminum or the like that is formed on a surface of the chip 1.

On the other hand, interconnections and a pad 4 made of aluminum or the like which is electrically connected to the interconnections are formed on a wiring board 10 such as a printed wiring board which supports the chip 1. The pad 4 is formed on a surface of the wiring board 10 on which the chip 1 is mounted, and the bump 3 formed on the chip 1 is connected to the pad 4. Additionally, a bump is attached to the other surface of the wiring board 10 via an unshown pad. This bump is used as an external connection terminal of the semiconductor device. Further, a sealing resin 5 is formed in paste or film state on the surface of the wiring board 10 on which the pad 4 is formed.

Next, the process of performing the flip chip after the resin is applied to the wiring board will be described referring to FIGS. 2 to 4.

A rear surface opposite to the element formation surface of the chip 1 is sucked and fixed on a stage 7 whose suction surface is formed of a porous member. The pad 2 and the bump 3 thereon are formed on the element formation surface of the chip 1. Moreover, a rear surface opposite to the pad formation surface of the wiring board 10 is sucked to a tool 8. This tool 8 is provided with a heating, pressurizing and ultrasonic wave vibration applying mechanism. The pad 4 covered with the resin 5 of the wiring board 10 is disposed opposite to the bump 3 of the chip 1.

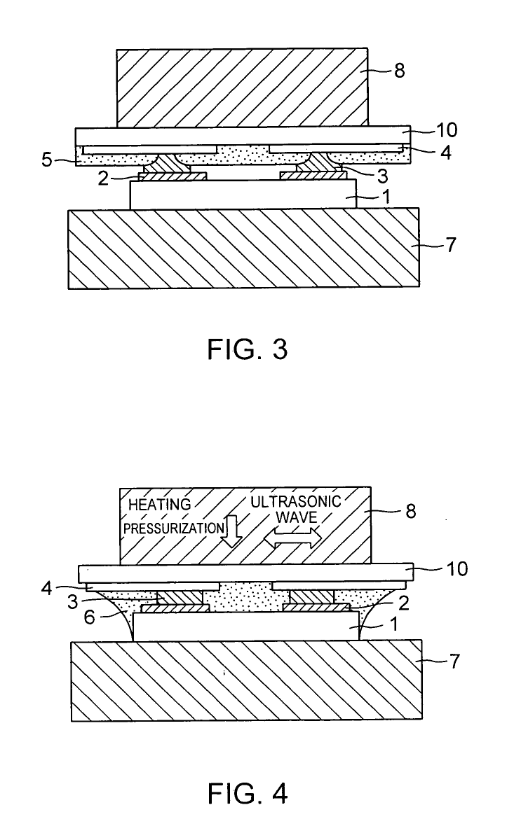

Next, the stage 7 is aligned with the tool 8 to adjust the bump 3 to the pad 4. Then, the tool 8 is lowered to face down the wiring board 10. In this state, the ultrasonic vibration is applied while pressurizing by the pressurizing and ultrasonic wave applying mechanism. At this point, the tool 8 is maintained at 100° C. (FIG. 2). Further, the ultrasonic vibration is continuously applied to soften the sealing resin 5 so that the bump 3 completely penetrates the sealing resin 5, and then the bump 3 and the pad 4 formed on the wiring board 10 are brought into contact and bonded together. In order to maintain the bonding temperature and resin sealing temperature, the sealing resin 5 is adequately fused, and a temperature at which the viscosity is the lowest is selected. This makes it possible for the bump 3 to penetrate the sealing resin 5 (FIG. 3). Further, the ultrasonic vibration is continuously applied to bond the pad 4 of the wiring board 10 to the bump 3, and they are electrically connected to each other, and then the resin 5 is hardened to form a resin sealed material 6 between the chip 1 and the wiring board 10.

As described above, according to this embodiment, the resin can be penetrated by the bump to reduce a connection failure. As shown in FIG. 7, satisfactory connection can be obtained because the resin does not intervene between the bump and the pad. Voids are prevented from being produced between the chip and the resin and between the wiring board and the sealing resin to reduce reliability declination. Moreover, the collective connection and sealing can be performed at a low temperature to reduce package warpage.

It should be noted that the stage 7 may be provided with at least one of the heating mechanism or the ultrasonic wave vibration applying mechanism according to need. In such a configuration, the flip chip bonding can be performed while the ultrasonic vibration is being applied to both the wiring board and the chip. In addition, the bump is formed on the pad on the chip in this embodiment, but the present invention is not limited to this embodiment, and the bump may be formed on the pad of the wiring board and may also be formed on each of the chip and the wiring board.

Next, a second embodiment will be described referring to FIGS. 8.

FIGS. 8A and 8B are sectional views explaining the process of performing the flip chip bonding after the resin is applied to the chip. A rear surface opposite to a pad formation surface of a wiring board 20 is sucked and fixed on a stage 27 whose suction surface is formed of a porous member. A pad 24 is formed on the pad formation surface of the wiring board 20. Further, the rear surface opposite to the element formation surface of the chip 21 is sucked to a tool 28. This tool 28 is provided with the heating, pressurizing and ultrasonic wave vibration applying mechanism. The pad 24 of the wiring board 20 is disposed opposite to a bump 23 on a pad 22 of the chip 21.

Next, the stage 27 is aligned with the tool 28 to adjust the bump 23 to the pad 24. Then, the tool 28 is lowered to face down the chip 21. In this state, the ultrasonic vibration is applied while pressurizing by the pressurizing and ultrasonic wave applying mechanism. At this time, the tool 28 is maintained at 100° C. Further, the ultrasonic vibration is continuously applied to soften a sealing resin 25 so that the bump 23 completely penetrates the sealing resin 25, and then the bump 23 and the pad 24 formed on the wiring board 20 are brought into contact and bonded together. In order to maintain the bonding and resin sealing temperature, the sealing resin 25 is adequately fused, and the temperature at which the viscosity is lowest is selected (the low viscosity area shown in FIG. 5 is preferable). This makes it possible for the bump 23 to penetrate the sealing resin 25. Further, the ultrasonic vibration is continuously applied so that the pad 24 on the wiring board 20 and the bump 23 on the chip 21 are bonded and electrically connected together, and the resin 25 is hardened to form a resin sealed material 26 between the chip 21 and the wiring board 20.

As described above, according to this embodiment, the resin can be penetrated by the bump to reduce the connection failure. Further, voids are prevented from being produced between the chip and the resin and between the wiring board and the resin to reduce reliability declination. Moreover, the collective connection and sealing can be performed at a low temperature to reduce the package warpage.

1. A manufacturing method of a semiconductor device to electrically connect a semiconductor chip and a wiring board via a first bump electrode, at least one of the semiconductor chip and the wiring board having a second bump electrode or a connection electrode, the method comprising:
collectively performing flip chip bonding of the semiconductor chip to the wiring board and resin sealing processing between the semiconductor chip and the wiring board;
wherein the collective processing includes controlling viscosity of a sealing resin with ultrasonic vibration so that the first bump electrode penetrates the sealing resin; and using the ultrasonic vibration to electrically connect the first bump electrode to the second bump electrode when at least one of the semiconductor chip and the wiring board has the second bump electrode, or using the ultrasonic vibration to electrically connect the first bump electrode to the connection electrode when at least one of the semiconductor chip and the wiring board has the connection electrode.

2. The manufacturing method of the semiconductor device according to claim 1,
wherein the viscosity of the sealing resin is 0.001 Pa·S to 100 Pa·S.

3. The manufacturing method of the semiconductor device according to claim 1,
wherein intensity of the ultrasonic vibration is 100 Hz to 100 kHz.

4. The manufacturing method of the semiconductor device according to claim 1,
wherein the flip chip bonding and the resin sealing are performed within a range of 20° C. to a temperature at which a reaction rate of the sealing resin is 50%.

5. The manufacturing method of the semiconductor device according to claim 1,
wherein a sum of height of the bump electrode formed on the semiconductor chip from a chip surface and height of the connection electrode of the wiring board from a wiring board surface is greater than thickness of the sealing resin after the flip chip bonding and resin sealing.

6. The manufacturing method of the semiconductor device according to claim 1,
wherein the ultrasonic vibration is applied from at least one side of the wiring board and the semiconductor chip.

7. The manufacturing method of the semiconductor device according to claim 1,
wherein the heating treatment is performed from at least one side of the wiring board and the semiconductor chip.

8. The manufacturing method of the semiconductor device according to claim 1,
wherein the first bump electrode is formed on the wiring board in advance.

9. The manufacturing method of the semiconductor device according to claim 1,
wherein the first bump electrode is formed on the semiconductor chip in advance.

10. The manufacturing method of the semiconductor device according to claim 1,
wherein the first bump electrode is formed on each of the wiring board and semiconductor chip in advance.

11. A manufacturing method of a semiconductor device to electrically connect a semiconductor chip and a wiring board via a first bump electrode, at least one of the semiconductor chip and the wiring board having a second bump electrode or a connection electrode, the method comprising:
collectively performing flip chip bonding of the semiconductor chip to the wiring board and resin sealing processing between the semiconductor chip and the wiring board;
wherein the collective processing includes controlling viscosity of a sealing resin with a heating treatment so that the first bump electrode penetrates the sealing resin; and using ultrasonic vibration to electrically connect the first bump electrode to the second bump electrode when at least one of the semiconductor chip and the wiring board has the second bump electrode, or using the ultrasonic vibration to electrically connect the first bump electrode to the connection electrode when at least one of the semiconductor chip and the wiring board has the connection electrode.

12. The manufacturing method of the semiconductor device according to claim 11,
wherein the viscosity of the sealing resin is 0.001 Pa·S to 100 Pa·S.

13. The manufacturing method of the semiconductor device according to claim 11,
wherein intensity of the ultrasonic vibration is 100 Hz to 100 kHz.

14. The manufacturing method of the semiconductor device according to claim 11,
wherein the flip chip bonding and the resin sealing are performed within a range of 20° C. to a temperature at which a reaction rate of the sealing resin is 50%.

15. The manufacturing method of the semiconductor device according to claim 11,
wherein a sum of height of the bump electrode formed on the semiconductor chip from a chip surface and height of the connection electrode of the wiring board from a wiring board surface is greater than thickness of the sealing resin after the flip chip bonding and resin sealing.

16. The manufacturing method of the semiconductor device according to claim 11,
wherein the ultrasonic vibration is applied from at least one side of the wiring board and the semiconductor chip.

17. The manufacturing method of the semiconductor device according to claim 11,
wherein the heating treatment is performed from at least one side of the wiring board and the semiconductor chip.

18. The manufacturing method of the semiconductor device according to claim 11,
wherein the first bump electrode is formed on the wiring board in advance.

19. The manufacturing method of the semiconductor device according to claim 11,
wherein the first bump electrode is formed on the semiconductor chip in advance.

20. The manufacturing method of the semiconductor device according to claim 11,
wherein the first bump electrode is formed on each of the wiring board and semiconductor chip in advance.
